(19) United States
(12) Patent Application Publication
(10) Pub. No.: US 2025/0338755 A1
(43) Pub. Date: Oct. 30, 2025

(54) DISPLAY DEVICE AND ELECTRONIC DEVICE INCLUDING THE SAME

(71) Applicant: Samsung Display Co., LTD., Yongin-si (KR)

(72) Inventors: Young Gil JI, Yongin-si (KR); Gun Tae PARK, Yongin-si (KR); Yong Kil PARK, Yongin-si (KR); Deu Ree JEONG, Yongin-si (KR); Jung Hee HAN, Yongin-si (KR)

(21) Appl. No.: 18/983,066

(22) Filed: Dec. 16, 2024

(30) Foreign Application Priority Data
Apr. 24, 2024 (KR) 10-2024-0054566

(51) Int. Cl. H10K 59/80

(52) U.S. Cl. CPC H10K 59/873

(57) ABSTRACT

A display device includes: a light emitting element; a thin film encapsulation layer on the light emitting element; a particle within the thin film encapsulation layer; a first insulating layer on the thin film encapsulation layer; a second insulating layer on the first insulating layer; and a protective layer on the second insulating layer and overlapping the particle, wherein the protective layer covers the thin film encapsulation layer, the first insulating layer, and the second insulating layer.

### CROSS-REFERENCE TO RELATED APPLICATION

The present application claims priority to and the benefit of Korean Patent Application No. 10-2024-0054566, filed on Apr. 24, 2024, in the Korean Intellectual Property Office, the entire disclosure of which is incorporated herein by reference.

### BACKGROUND

### 1. Field

Aspects of some embodiments of the present disclosure relate to a display device and an electronic device including the same.

### 2. Description of the Related Art

Recently, as interest in an information display is increasing, research and development for display devices is continuously being conducted.

The above information disclosed in this Background section is only for enhancement of understanding of the background and therefore the information discussed in this Background section does not necessarily constitute prior art.

### SUMMARY

Aspects of some embodiments of the present include a display device with relatively improved reliability.

Embodiments of the present disclosure are not limited to the above-discussed characteristics, and other characteristics that are not specifically mentioned may be clearly understood to a person of an ordinary skill in the art using the following description.

According to some embodiments of the present disclosure, a display device includes: a light emitting element; a thin film encapsulation layer on the light emitting element; a particle within the thin film encapsulation layer; a first insulating layer on the thin film encapsulation layer; a second insulating layer on the first insulating layer; and a protective layer on the second insulating layer and overlapping the particle, wherein the protective layer covers the thin film encapsulation layer, the first insulating layer, and the second insulating layer.

According to some embodiments, the thin film encapsulation layer may include a first inorganic film, a second inorganic film, and an organic film between the first inorganic film and the second inorganic film.

According to some embodiments, the first inorganic film may cover a surface of the particle.

According to some embodiments, a thickness of the second inorganic film may be thicker than that of the protective layer.

According to some embodiments, a thickness of the first inorganic film may be thicker than that of the second inorganic film.

According to some embodiments, the display device may further include a first conductive layer between the first insulating layer and the second insulating layer.

According to some embodiments, the display device may further include a second conductive layer on the second insulating layer.

According to some embodiments, the first conductive layer may include first sensing electrodes arranged in a first direction and second sensing electrodes arranged in a second direction intersecting the first direction, and the second conductive layer includes a connection electrode connecting the first sensing electrodes.

According to some embodiments, the display device may further include a third insulating layer on the second conductive layer.

According to some embodiments, the protective layer may be between the second insulating layer and the third insulating layer.

According to some embodiments of the present disclosure, a display device includes: a light emitting element; a thin film encapsulation layer on the light emitting element; a particle within the thin film encapsulation layer; and an insulating layer on the thin film encapsulation layer, wherein the encapsulation layer and the insulating layer include a curved portion that overlaps the particle, and a protective layer on the insulating layer and covering the curved portion is included.

According to some embodiments, the thin film encapsulation layer may include a first inorganic film, a second inorganic film, and an organic film between the first inorganic film and the second inorganic film.

According to some embodiments, the first inorganic film may cover a surface of the particle.

According to some embodiments, a thickness of the second inorganic film may be thicker than that of the protective layer.

According to some embodiments, a thickness of the first inorganic film may be thicker than that of the second inorganic film.

According to some embodiments, the protective layer may include a metallic material.

According to some embodiments, the insulating layer may include a first inorganic insulating layer on the thin film encapsulation layer and a second inorganic insulating layer on the first inorganic insulating layer.

According to some embodiments, the protective layer may be on the second inorganic insulating layer.

According to some embodiments, the insulating layer may further include an organic insulating layer on the second inorganic insulating layer.

According to some embodiments, the protective layer may be between the second inorganic insulating layer and the organic insulating layer.

Further details according to some embodiments are included in the detailed description and drawings.

According to some embodiments, by preventing or reducing etching of the encapsulation layer in the process of forming the sensing layer, it may be possible to prevent, reduce, or minimize the decrease in reliability of the display device due to damage to the encapsulation layer.

According to some embodiments of the present disclosure, an electronic device includes: a processor to provide input image data; and a display device to display an image based on the input image data, the display device including sub-pixel areas, wherein the display device comprises a light emitting element; a thin film encapsulation layer on the light emitting element; a particle within the thin film encapsulation layer; a first insulating layer on the thin film encapsulation layer; a second insulating layer on the first insulating layer; and a protective layer on the second insulating layer and overlapping the particle, wherein the protective layer covers the thin film encapsulation layer, the first insulating layer, and the second insulating layer.

Aspects of embodiments of the present disclosure are not limited by what is illustrated in the above, and more various characteristics are included in the present specification.

### BRIEF DESCRIPTION OF THE DRAWINGS

FIG. 1 illustrates a perspective view of a display device according to some embodiments.

FIG. 2 illustrates a cross-sectional view of a display device according to some embodiments.

FIG. 3 illustrates a top plan view of a display panel according to some embodiments.

FIG. 4 illustrates a cross-sectional view of a display panel according to some embodiments.

FIG. 5 illustrates a top plan view of a sensing layer according to some embodiments.

FIG. 6 illustrates an enlarged top plan view of an area A of FIG. 5.

FIG. 7 illustrates a cross-sectional view taken along the line B-B′ of FIG. 6.

FIG. 8 and FIG. 9 illustrate cross-sectional views of a protective layer according to some embodiments.

FIG. 10 to FIG. 16 illustrate cross-sectional views of process steps of a manufacturing method of a display device according to some embodiments.

FIG. 17 is a schematic block diagram illustrating an electronic device including a display device in accordance with an embodiment.

FIG. 18 is a schematic diagram illustrating an example where the electronic device of FIG. 17 is a smartphone.

FIG. 19 is a schematic diagram illustrating an example where the electronic device of FIG. 17 is a tablet computer.

### DETAILED DESCRIPTION

Aspects and features of embodiments according to the present disclosure and methods of accomplishing the same may be understood more readily by reference to the following detailed description of the disclosed embodiments and the accompanying drawings. The present disclosure may, however, be embodied in different forms and should not be construed as limited to the embodiments set forth herein. The present embodiments are provided so that this disclosure will be more thorough and more complete, and will more fully convey the scope of embodiments according to the present disclosure to those skilled in the art, and further, embodiments according to the present disclosure are defined by the appended claims, and their equivalents.

The terms used herein are for the purpose of describing particular embodiments only and is not intended to be limiting. As used herein, the singular forms “a”, “an” and “the” are intended to include the plural forms as well, unless the context clearly indicates otherwise. It will be further understood that the terms “comprise” and/or “comprising”, “include” or “including”, and “have” or “having”, when used in the present disclosure, specify the presence of stated elements, steps, operations, and/or devices, but do not preclude the presence or addition of one or more other elements, steps, operations, and/or devices.

The term “connection” or “coupling” may comprehensively mean a physical and/or electrical connection or coupling. This may comprehensively mean a direct or indirect connection or coupling, and an integrated or non-integrated connection or coupling.

It will be understood that when an element or a layer is referred to as being ‘on’ another element or layer, it can be directly on another element or layer, or intervening element or layer may also be present. Throughout the specification, the same reference numerals denote the same constituent elements.

Although the terms “first”, “second”, and the like are used to describe various constituent elements, these constituent elements are not limited by these terms. These terms are merely used to distinguish one constituent element from another. Therefore, the first constituent elements described below may be the second constituent elements within the technical spirit of the present disclosure.

Hereinafter, aspects of some embodiments of the present disclosure will be described in more detail with reference to the accompanying drawings.

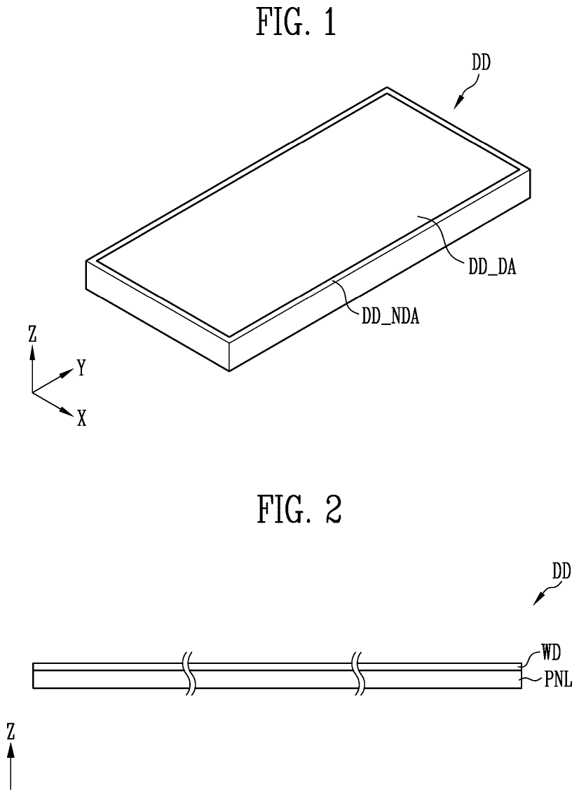

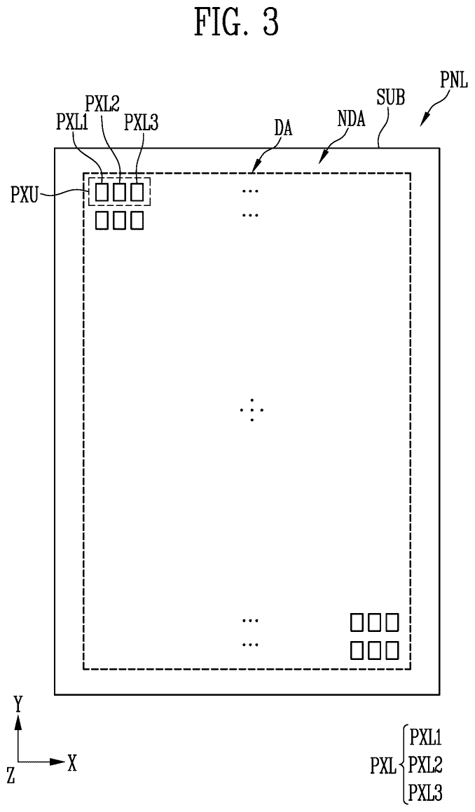

FIG. 1 illustrates a perspective view of a display device according to some embodiments. FIG. 2 illustrates a cross-sectional view of a display device according to some embodiments. FIG. 3 illustrates a top plan view of a display panel according to some embodiments.

Referring to FIG. 1 to FIG. 3, a display device DD may include a display panel PNL and a window WD.

The display device DD may include a display area DD_DA that displays images and a non-display area DD_NDA that does not display images. The non-display area DD_NDA may be provided in at least one side of the display area DD_DA. For example, the non-display area DD_NDA may be provided to surround (e.g., in a periphery or outside a footprint of) the display area DD_DA.

The display device DD may be provided to have a rectangular plate shape having angled corners in a plan view (e.g., from a view toward a display surface of the display device DD), but according to some embodiments, the corners of the display device DD may have a curved shape. However, embodiments according to the present disclosure are not necessarily limited thereto, and the display device DD may be implemented in various shapes (e.g., a circular shape, an elliptical shape, a square shape, a polygonal shape, or an irregular shape).

The display device DD may be applied to an electronic device in which a display surface is applied to at least one surface thereof such as a smart phone, a television, a tablet PC, a mobile phone, an image phone, an electron book reader, a desktop PC, a laptop PC, a netbook computer, a workstation, a server, a PDA, a portable multimedia player (PMP), an MP3 player, a medical device, a camera, or a wearable display device.

The display panel PNL and a substrate SUB for forming the display panel may include a display area DA for displaying images and a non-display area NDA excluding the display area DA. The display area DA may configure a screen on which an image is displayed, and the non-display area NDA may be the remaining area excluding the display area DA.

For better understanding and ease of description, FIG. 3 briefly illustrates a structure of the display panel PNL based on a display area DA. However, according to some embodiments, at least one driving circuit portion (for example, at least one of a scan driver and a data driver), wires, and/or pads may be further located in the display panel PNL.

A pixel unit PXU may be located in the display area DA. The pixel unit PXU may include a first pixel PXL1, a second pixel PXL2, and/or a third pixel PXL3. Hereinafter, when arbitrarily referring to at least one of the first pixel PXL1, the second pixel PXL2, or the third pixel PXL3, or when comprehensively referring to two or more types of pixels thereof, they will be referred to as a “pixel PXL” or “pixels PXL”.

The pixels PXL may be regularly arranged according to a stripe or PENTILE™ arrangement structure. However, the arrangement structure of the pixels PXL is not limited thereto, and the pixels PXL may be arranged in the display area DA in various structures and/or methods.

According to some embodiments, two or more types of pixels PXL emitting light of different colors may be located in the display area DA. For example, in the display area DA, a first pixels PXL1 emitting light of the first color, a second pixels PXL2 emitting light of the second color, and a third pixels PXL3 emitting light of the third color may be arranged. At least one of the first to third pixels PXL1, PXL2, or PXL3 arranged to be adjacent to each other may form one pixel unit PXU that may emit light of various colors. For example, the first pixel PXL1 may be a red pixel that emits red light, the second pixel PXL2 may be a green pixel that emits green light, and the third pixel PXL3 may be a blue pixel that emits blue light, but embodiments according to the present disclosure are not limited thereto. FIG. 3 illustrates a case in which the pixel unit PXU includes one first pixel PXL1, one second pixel PXL2, and one third pixel PXL3, but embodiments according to the present disclosure are not necessarily limited thereto, and the pixel unit PXU may include one first pixel PXL1, two second pixels PXL2, and one third pixel PXL3.

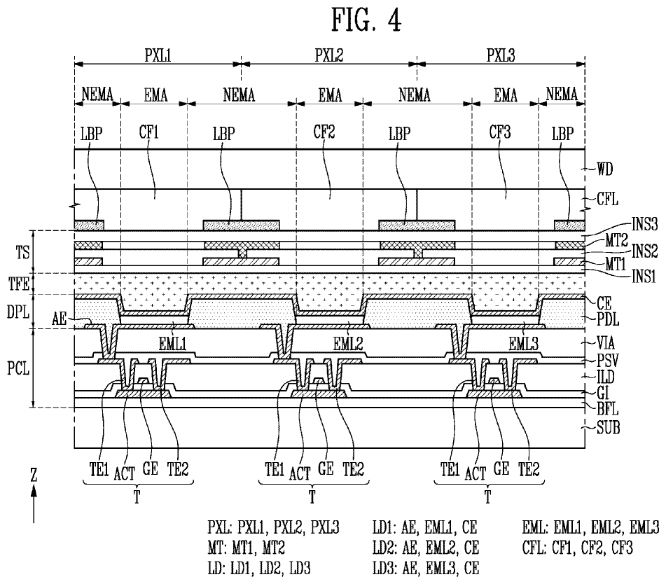

The first pixel PXL1, the second pixel PXL2, and the third pixel PXL3 include a first light emitting element (LD1 in FIG. 4), a second light emitting element (LD2 in FIG. 4), and a third light emitting element (LD3 in FIG. 4) as light sources, respectively, so that they may emit light of the first color, light of the second color, and light of the third color, respectively. However, the color of light emitted by each pixel PXL may be variously changed.

The window WD for protecting an exposed surface of the display panel PNL may be provided on the display panel PNL. The window WD may protect the display panel PNL from external impact, and may provide an input surface and/or a display surface to a user. The window WD may be combined with the display panel PNL by using an optically clear adhesive member.

The window WD may have a multi-layered structure selected from a glass substrate, a plastic film, and a plastic substrate. The multi-layered structure may be formed through a continuous process or an adhesive process using an adhesive layer. The window WD may be entirely or partially flexible.

FIG. 4 illustrates a cross-sectional view of a display panel according to some embodiments.

Referring to FIG. 4, the first to third pixels PXL1, PXL2, and PXL3 each include a light emitting area EMA, and a non-light emitting area NEMA may be located between the light emitting area EMA of each of the first to third pixels PXL1, PXL2, and PXL3.

The first to third pixels PXL1, PXL2, and PXL3 may each include a pixel circuit layer PCL, a display element layer DPL, and a thin film encapsulation layer TFE sequentially located on a substrate SUB.

The substrate SUB may form a base surface. The substrate SUB may include a transparent insulating material to transmit light. The substrate SUB may be a rigid substrate or a flexible substrate. For example, the rigid substrate may be one of a glass substrate, a quartz substrate, a glass ceramic substrate, and a crystalline glass substrate. The flexible substrate may be one of a film substrate and a plastic substrate, which include a polymer organic material. For example, the flexible substrate may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, or cellulose acetate propionate, but embodiments according to the present disclosure are not limited thereto.

The pixel circuit layer PCL may include a pixel circuit provided on the substrate SUB. The pixel circuit layer PCL may include a sensor circuit provided on the substrate SUB.

The pixel circuit layer PCL may include a buffer layer BFL, a gate insulating layer GI, an interlayer insulating layer ILD, a passivation layer PSV, and a via layer VIA that are sequentially stacked on the substrate SUB along a third direction (a Z-axis direction).

The buffer layer BFL may be an inorganic insulating layer including an inorganic material. The buffer layer BFL may include at least one of metal oxides such as a silicon nitride (SiNx), a silicon oxide (SiOx), a silicon oxynitride (SiOxNy), or an aluminum oxide (AlOx). The buffer layer BFL may be provide as a single layer, but may also be provide as a multilayer of at least double layers or more. When the buffer layer BFL is provided as the multiple layers, respective layers thereof may be made of the same material or different materials. The buffer layer BFL may be omitted depending on the material, and process condition, and the like of the substrate SUB.

A transistor T may be located on the buffer layer BFL. The transistor T may include an active pattern ACT, a gate electrode GE, a first transistor electrode TE1, and a second transistor electrode TE2.

The active pattern ACT may be located on the buffer layer BFL. The active pattern ACT may include a polysilicon semiconductor. For example, the active pattern ACT may be formed through a low temperature polysilicon process. However, embodiments according to the present disclosure are not necessarily limited thereto, and the active pattern ACT may be formed of an oxide semiconductor, a metal oxide semiconductor, or the like.

Each active pattern ACT may include a channel area, a first contact area connected to one end of the channel area, and a second contact area connected to the other end of the channel area. The channel area, the first contact area, and the second contact area may be formed of a semiconductor layer in which an impurity is not doped or an impurity is doped. For example, the first contact area and the second contact area may be formed of a semiconductor layer doped with an impurity, and the channel area may be formed of a semiconductor layer that is not doped with an impurity. As the impurity, for example, a p-type impurity may be used, but embodiments according to the present disclosure are not limited thereto. One of the first and second contact areas may be a source area, and the other thereof may be a drain area.

The gate insulating layer GI may be located on the active pattern ACT. The gate insulating layer GI may be an inorganic film (or inorganic insulating film) including an inorganic material. For example, the gate insulating layer GI may include at least one of metal oxides such as a silicon nitride (SiNx), a silicon oxide (SiOx), a silicon oxynitride (SiOxNy), or an aluminum oxide (AlOx). However, the material of the gate insulating layer GI is not limited to the above-described embodiments. According to some embodiments, the gate insulating layer GI may be formed as an organic film (or organic insulating film) including an organic material. The gate insulating layer GI may be provided as a single layer, and may be provided as a multilayer of at least double layers or more.

The gate electrode GE may be located on the gate insulating layer GI. The gate electrode GE may overlap a channel area of the active pattern ACT. The gate electrode GE may be formed to have a single-layered structure of a single or a mixture thereof selected from a group consisting of copper (Cu), molybdenum (Mo), tungsten (W), aluminum neodymium (AlNd), titanium (Ti), aluminum (Al), silver (Ag), and an alloy thereof, or in order to reduce wire resistance, it may be formed to have a double-layered or multi-layered structure of molybdenum (Mo), titanium (Ti), copper (Cu), aluminum (Al) or silver (Ag), which are a low-resistance material.

The interlayer insulating layer ILD may be located on the gate electrode GE. The interlayer insulating layer ILD may include the same material as that of the gate insulating layer GI, or may include one or more materials selected from the materials illustrated as constituent materials of the gate insulating layer GI.

The first transistor electrode TE1 and the second transistor electrode TE2 may be located on the interlayer insulating layer ILD.

The first transistor electrode TE1 of the transistor T may contact the first contact area of the active pattern ACT through a contact hole penetrating the interlayer insulating layer ILD and the gate insulating layer GI. When the first contact area is a source area, the first transistor electrode TE1 may be a first source electrode.

The second transistor electrode TE2 of the transistor T may contact the second contact area of the other end of the active pattern ACT through a contact hole penetrating the interlayer insulating layer ILD and the gate insulating layer GI. When the second contact area is a drain area, the second transistor electrode TE2 may be a second drain electrode.

The first transistor electrode TE1 and the second transistor electrode TE2 may each include the same material as the gate electrode GE or include one or more materials selected from the materials illustrated and/or described as a constituent material of the gate electrode GE.

The passivation layer PSV may be located on the first transistor electrode TE1 and the transistor electrodes TE2. The passivation layer PSV (for example, protection layer) may be an inorganic film (or an inorganic insulating film) including an inorganic material or an organic film (or an organic insulating film) including an organic material. The inorganic film may include, for example, at least one of metal oxides such as a silicon nitride (SiNx), a silicon oxide (SiOx), a silicon oxynitride (SiOxNy), or an aluminum oxide (AlOx). The organic film may include at least one of, for example, a polyacrylates resin, an epoxy resin, a phenolic resin, a polyamides resin, a polyimides resin, an unsaturated polyesters resin, a polyphenylen ethers resin, a polyphenylene sulfides resin, or a benzocyclobutene resin.

According to some embodiments, the passivation layer PSV may include the same material as the interlayer insulating layer ILD, but is not limited thereto. The passivation layer PSV may be provided as a single layer, but may also be provide as a multilayer of at least double layers or more.

The via layer VIA may be located on the passivation layer PSV. The via layer VIA may include the same material as the passivation layer PSV, or may include one or more materials selected from materials illustrated and/or described as constituent materials of the passivation layer PSV. According to some embodiments, the via layer VIA may be an organic film made of an organic material.

The display element layer DPL may be located on the pixel circuit layer PCL.

The display element layer DPL may include the light emitting element LD that emits light. The first to third pixels PXL1, PXL2, and PXL3 may include the first to third light emitting elements LD1, LD2, and LD3, respectively.

The first light emitting element LD1 may include an anode AE, a first light emitting layer EML1, and a cathode CE. The second light emitting element LD2 may include an anode AE, a second light emitting layer EML2, and a cathode CE. The third light emitting device LD3 may include an anode electrode AE, a third light emitting layer EML3, and a cathode CE. For example, the first to third light emitting elements LD1, LD2, and LD3 may be top light emitting type organic light emitting elements.

The anode electrodes AE of respective pixels PXL are located in the light emitting area EMA, and may be spaced apart from each other. The anode electrode AE of each pixel PXL may be electrically connected to the first transistor electrode TE1 of the transistor T of each pixel PXL through a contact hole penetrating the via layer VIA and the passivation layer PSV.

A bank PDL may be located on the anode electrode AE. The bank PDL may define (or partition) the light emitting area EMA of each pixel PXL. The bank PDL may include an opening partially exposing the anode electrode AE of each pixel PXL.

The bank PDL may be an organic insulating layer made of an organic material. The organic material may include an acrylic resin, an epoxy resin, a phenol resin, a polyamide resin, a polyimide resin, and the like.

According to some embodiments, the bank PDL may include a light absorbing material, or may serve to absorb light introduced from the outside by a light absorption agent being applied thereon. For example, the bank PDL may include a carbon-based black pigment. However, embodiments according to the present disclosure are not necessarily limited thereto, and the bank PDL may include an opaque metallic material such as chromium (Cr), molybdenum (Mo), an alloy (MoTi) of molybdenum (Mo) and titanium (Ti), tungsten (W), vanadium (V), niobium (Nb), tantalum (Ta), manganese (Mn), cobalt (Co), or nickel (Ni), which has a high light absorption rate.

The light emitting layer EML of each pixel PXL may be located on the anode electrode AE exposed by the bank PDL. The cathode electrode CE may be located on the light emitting layer EML. The cathode electrode CE may be entirely arranged on the first to third pixels PXL1, PXL2, and PXL3. For example, the cathode electrode CE may be provided as a common electrode, but embodiments according to the present disclosure are not necessarily limited thereto.

The cathode electrode CE be formed of a metal layer of Ag (silver), Mg (magnesium), Al (aluminum), Pt (platinum), Pd (palladium), Au (gold), Ni (nickel), Nd (neodymium), Ir (iridium), Cr (chromium), and an alloy thereof and/or a transparent conductive layer of an ITO (indium tin oxide), an IZO (indium zinc oxide), a ZnO (zinc oxide), and ITZO (indium tin zinc oxide). According to some embodiments, the cathode electrode CE may be formed of a multilayer of a double layer or more including a thin metal layer, for example, a triple layer of ITO/Ag/ITO.

The thin film encapsulation layer TFE may be located on the display element layer DPL. The thin film encapsulation layer TFE may have a single-layered structure or a multi-layered structure. The thin film encapsulation layer TFE may include a plurality of insulating layers covering the light emitting element LD. The thin film encapsulation layer TFE may include at least one inorganic film and at least one organic film. For example, the thin film encapsulation layer TFE may have a structure in which an inorganic film and an organic film are alternately stacked. For example, the thin film encapsulation layer TFE may include a first inorganic film, an organic layer located on the first inorganic film, and a second inorganic film located on the organic film.

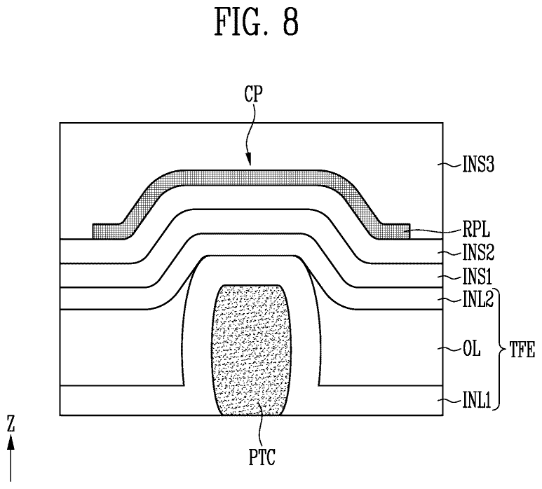

According to some embodiments, particles (PCT in FIG. 8) may be provided inside the thin film encapsulation layer TFE. The particles PCT may be foreign substances generated during a process of manufacturing the display device. The particles PCT and the resulting curved portion (CP in FIG. 8) will be described in more detail later with reference to FIG. 8.

A sensing layer TS may be located on the thin film encapsulation layer TFE. The sensing layer TS may include a first insulating layer INS1, a first conductive layer MT1, a second insulating layer INS2, a second conductive layer MT2, and/or a third insulating layer INS3.

The first insulating layer INS1 may be located on the thin film encapsulation layer TFE. The first insulating layer INS1 may be an inorganic insulating layer including an inorganic material. The inorganic insulating layer may include an inorganic insulating material such as a silicon oxide (SiOx), a silicon nitride (SiNx), a silicon oxynitride (SiOxNy), an aluminum oxide (AlxOy), a titanium oxide (TiOx), a tantalum oxide (TaxOy), a hafnium oxide (HfOx), or a zinc oxide (ZnOx). According to some embodiments, the first insulating layer INS1 may be omitted, or may be configured as the uppermost layer of a thin film encapsulation layer TFE.

The first conductive layer MT1 may be located on the first insulating layer INS1. The first conductive layer MT1 may be partially opened so as to not overlap the light emitting element LD of each pixel PXL. For example, the first conductive layer MT1 may be arranged to overlap the non-light emitting area NEMA around the light emitting area EMA.

The first conductive layer MT1 may include a metal layer or a transparent conductive layer. For example, the metal layer may include molybdenum, titanium, copper, aluminum, and an alloy thereof. The transparent conductive layer may include one of an indium tin oxide (ITO), an indium zinc oxide (IZO), a zinc oxide (ZnO), an indium tin zinc oxide (ITZO), a PEDOT, and a metal nano wire, but is not necessarily limited thereto. The first conductive layer MT1 may form a connection electrode that connects sensing electrodes.

The second insulating layer INS2 may be located on the first conductive layer MT1. The second insulating layer INS2 may include the same material as the first insulating layer INS1 described above, or may include one or more materials selected from the materials illustrated as constituent materials of the first insulating layer INS1

The second conductive layer MT2 may be located on the second insulating layer INS2. The second conductive layer MT2 may be partially opened so as to not overlap the light emitting element LD of each pixel PXL. For example, the second conductive layer MT2 may be arranged to overlap the non-light emitting area NEMA around the light emitting area EMA.

The second conductive layer MT2 may include the same material as the first conductive layer MT1 described above, or may include one or more materials selected from the materials illustrated as constituent materials of the first conductive layer MT1.

The second conductive layer MT2 may be electrically connected to the first conductive layer MT1 through a contact hole penetrating the second insulating layer INS2. The second conductive layer MT2 may form sensing electrodes.

The third insulating layer INS3 may be located on the second conductive layer MT2. The third insulating layer INS3 may be an organic insulating layer including an organic material. However, it is not necessarily limited thereto, and according to some embodiments, the third insulating layer INS3 may be made of an inorganic film or may have a structure in which organic films and inorganic films are alternately stacked.

A light blocking layer LBP may be located on the display element layer DPL, the thin film encapsulation layer TFE, and/or the sensing layer TS. The light blocking layer LBP may include an opening overlapping the light emitting element LD. For example, the light blocking layer LBP may be arranged to overlap the non-light emitting area NEMA around the light emitting area EMA.

The light blocking layer LBP may include a light blocking material to prevent or reduce light leakage and color mixing defects. For example, the light blocking layer LBP may include a black matrix, but is not necessarily limited thereto. According to some embodiments, the light blocking layer LBP may include a carbon black (CB) and/or a titanium black (TiBK).

A color filter layer CFL may be located on the light blocking layer LBP. The color filter layer CFL may include color filters CF1, CF2, and CF3 matching the color of each pixel PXL. A full-color image may be displayed by arranging the color filters CF1, CF2, and CF3 matching respective colors of the first to third pixels PXL1, PXL2, and PXL3.

The color filter layer CFL may include a first color filter CF1 that is located in the first pixel PXL1 to selectively transmit light emitted by the first pixel PXL1, a second color filter CF2 that is located in the second pixel PXL2 to selectively transmit light emitted by the second pixel PXL2, and a third color filter CF3 that is located in the third pixel PXL3 to selectively transmit light emitted by the third pixel PXL3.

According to some embodiments, the first color filter CF1, the second color filter CF2, and the third color filter CF3 may be a red color filter, a green color filter, and a blue color filter respectively, but embodiments according to the present disclosure are not limited necessarily thereto. Hereinafter, when referring to one of the first color filter CF1, the second color filter CF2, and the third color filter CF3, or when comprehensively referring to two or more thereof, it will be referred to as the “color filter CF” or “color filters CF”.

The first color filter CF1 may include a color filter material that selectively transmits light of a first color (or red color). For example, when the first pixel PXL1 is a red pixel, the first color filter CF1 may include a red color filter material.

The second color filter CF2 may include a color filter material that selectively transmits light of a second color (or green color). For example, when the second pixel PXL2 is a green pixel, the second color filter CF2 may include a green color filter material.

The third color filter CF3 may include a color filter material that selectively transmits light of a third color (or blue color). For example, when the third pixel PXL3 is a blue pixel, the third color filter CF3 may include a blue color filter material.

A window WD may be provided on the color filter layer CFL. The window WD may protect a lower member from external impact and provide an input surface and/or a display surface to a user.

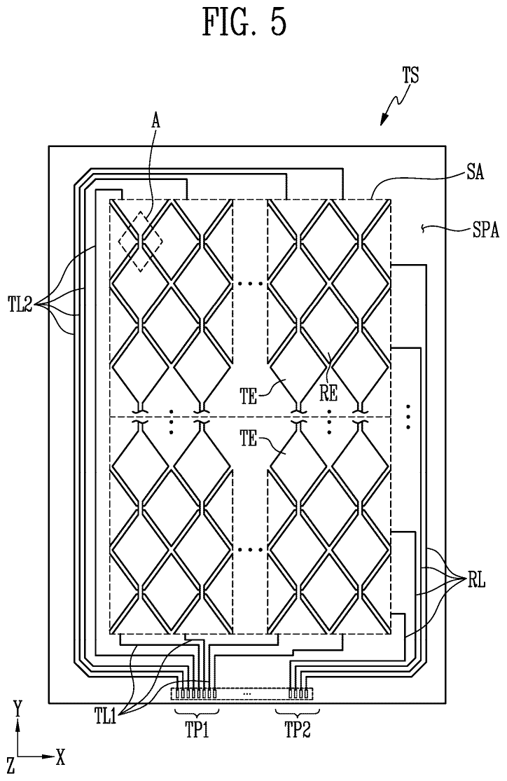

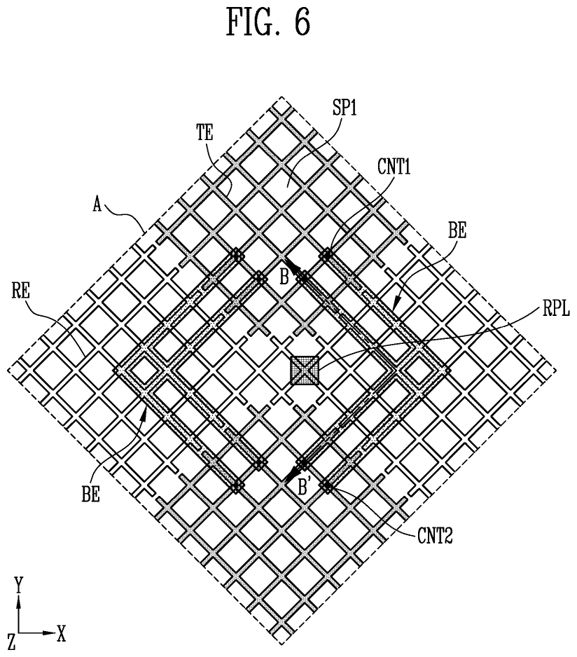

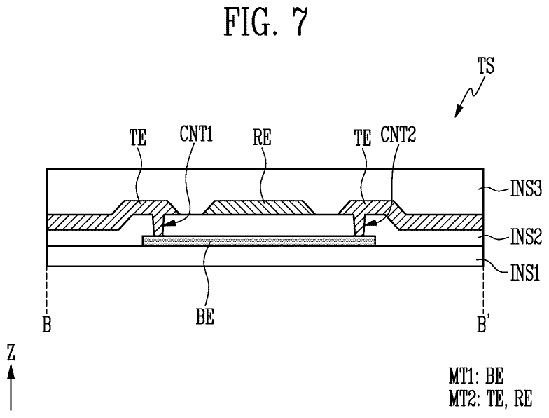

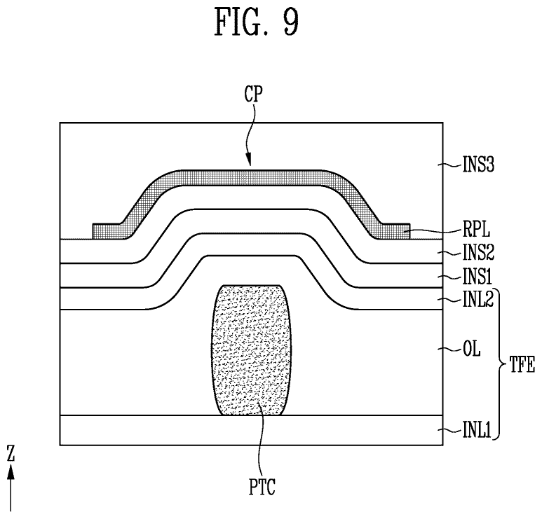

FIG. 5 illustrates a top plan view of a sensing layer according to some embodiments. FIG. 6 illustrates an enlarged top plan view of an area A of FIG. 5. FIG. 7 illustrates a cross-sectional view taken along the line B-B′ of FIG. 6. FIG. 8 and FIG. 9 illustrates cross-sectional views of a protective layer according to some embodiments.

Referring to FIG. 5, the sensing layer TS includes a sensing area SA for detecting a user's touch and a sensing peripheral area SPA arranged around the sensing area SA. The sensing area SA may overlap the display area DA, and the sensing peripheral area SPA may overlap the non-display area NDA.

First sensing electrodes TE may be arranged along a second direction (Y-axis direction) and may be electrically connected to each other. Second sensing electrodes RE may be arranged along a first direction (X-axis direction) intersecting the second direction (Y-axis direction) and may be electrically connected to each other. The first sensing electrodes TE and the second sensing electrodes RE may be electrically separated from each other. The first sensing electrodes TE and the second sensing electrodes RE may be arranged to be spaced apart from each other.

Referring to FIG. 6, the first sensing electrodes TE adjacent to each other in the second direction (Y-axis direction) may be electrically connected to each other by connection electrodes BE, and the first sensing electrodes TE adjacent to each other in the first direction (X-axis direction) may be insulated from each other. In addition, the second sensing electrodes RE adjacent to each other in the first direction (X-axis direction) may be electrically connected to each other, and the second sensing electrodes RE adjacent to each other in the second direction (Y-axis direction) may be electrically insulated from each other. Accordingly, mutual capacitance may be formed at the intersection of the first sensing electrodes TE and the second sensing electrodes RE. By detecting the voltage charged in the mutual capacitance, it is possible to determine whether the user touches or not.

The connection electrodes BE may be connected to the first sensing electrodes TE adjacent to each other in the second direction (Y-axis direction) through a first contact hole CNT1 and a second contact hole CNT2, respectively. One end of the connection electrode BE may be connected to one of the first sensing electrodes TE adjacent to each other in the second direction (Y-axis direction) through the first contact hole CNT1. The other end of the connection electrode BE may be connected to another first sensing electrode TE among the first sensing electrodes TE adjacent to each other in the second direction (Y-axis direction) through the second contact hole CNT2. A structure in which the first sensing electrodes TE are connected by a pair of connection electrodes BE is illustrated in the drawings, but embodiments according to the present disclosure are not limited thereto. For example, the connection electrode BE may include a plurality of sub-connection electrodes configured of several pairs.

The first sensing electrode TE and the second sensing electrode RE may be formed in a mesh shape or a web shape. In this case, lowering of the luminance of the light emitted from the pixel PXL by the first sensing electrode TE and the second sensing electrode RE may be prevented or reduced. To this end, mesh structures of the first sensing electrode TE and the second sensing electrode RE may be arranged to overlap the non-light emitting area (NEMA in FIG. 4).

Referring back to FIG. 5, sensing pads TP1 and TP2 and sensing lines TL1, TL2, and RL may be located in the sensing peripheral area SPA.

The sensing pads TP1 and TP2 may be located on one side of the sensing peripheral area SPA. The sensing pads TP1 and TP2 may include a first sensing pad TP1 and a second sensing pad TP2.

The sensing lines TL1, TL2, and RL may include driving lines TL1 and TL2 connected to the first sensing electrode TE and a sensing line RL connected to the second sensing electrode RE.

The driving lines TL1 and TL2 may include a first driving line TL1 connected to the first sensing electrode TE located on one side of the sensing area SA and a second driving line TL2 connected to the first sensing electrode TE located on the other side of the sensing area SA. Here, one side of the sensing area SA may mean a lower side of the sensing area SA, and the other side of the sensing area SA may mean an upper side of the sensing area SA. The upper and lower sides of the sensing area SA may be opposite to each other. For example, as shown in FIG. 5, the first sensing electrode TE located at the lower end of the first sensing electrodes TE electrically connected in the second direction (Y-axis direction) may be connected to the first driving line TL1, and the first sensing electrode TE located at the upper end of the first sensing electrodes TE electrically connected in the second direction (Y-axis direction) may be connected to the second driving line TL2.

The second driving line TL2 may be connected to the first sensing electrode TE on the upper side of the sensing area SA via the left side of the sensing area SA. One ends of the driving lines TL1 and TL2 may be connected to the first sensing electrode TE, and the other ends of the driving lines TL1 and TL2 may be connected to the first sensing pad TP1.

The second sensing electrodes RE located on one side of the sensing area SA may be connected to the sensing lines RL. For example, as shown in FIG. 5, among the second sensing electrodes RE electrically connected in the first direction (X-axis direction), the second sensing electrode RE located on the right side may be connected to the sensing line RL. One end of the sensing line RL may be connected to the second sensing electrode RE, and the other end of the sensing line RL may be connected to the second sensing pad TP2.

Referring to FIG. 7, the first conductive layer MT1 may include the connection electrode BE described above. The second conductive layer MT2 may include the first sensing electrodes TE and the second sensing electrodes RE described above.

One of the adjacent first sensing electrodes TE may be electrically connected to one end of the connection electrode BE through the first contact hole CNT1 penetrating the second insulating layer INS2. The other of the adjacent first sensing electrodes TE may be electrically connected to the other end of the connection electrode BE through the second contact hole CNT2 penetrating the second insulating layer INS2.

In addition, the first insulating layer INS1, the first conductive layer MT1, the second insulating layer INS2, the second conductive layer MT2, and/or the third insulating layer INS3 of the sensing layer TS have been described in detail with reference to FIG. 4 and the like, so some redundant description may be omitted.

Referring to FIG. 8, a particle PTC may be provided in the thin film encapsulation layer TFE. The thin film encapsulation layer TFE may include a first inorganic film INL1, an organic film OL located on the first inorganic film INL1, and a second inorganic film INL2 located on the organic film OL. The organic film OL may be located between the first inorganic film INL1 and the second inorganic film INL2.

The first inorganic film INL1 may include at least one of an inorganic insulating material such as a silicon oxide (SiOx), a silicon nitride (SiNx), a silicon oxynitride (SiOxNy), an aluminum oxide (AlxOy), a titanium oxide (TiOx), a tantalum oxide (TaxOy), a hafnium oxide (HfOx), or a zinc oxide (ZnOx).

The organic film OL may include at least one of a polyacrylates resin, an epoxy resin, a phenolic resin, a polyamides resin, a polyimides resin, an unsaturated polyesters resin, a polyphenylen ethers resin, a polyphenylene sulfides resin, or a benzocyclobutene resin.

The second inorganic film INL2 may include at least one of an inorganic insulating material such as a silicon oxide (SiOx), a silicon nitride (SiNx), a silicon oxynitride (SiOxNy), an aluminum oxide (AlxOy), a titanium oxide (TiOx), a tantalum oxide (TaxOy), a hafnium oxide (HfOx), or a zinc oxide (ZnOx).

A thickness of the first inorganic film INL1 in the third direction (Z-axis direction) may be greater than a thickness of the second inorganic film INL2 in the third direction (Z-axis direction). A thickness of the organic film OL in the third direction (Z-axis direction) may be greater than a thickness of the first inorganic film INL1 in the third direction (Z-axis direction). However, embodiments according to the present disclosure are not necessarily limited thereto, and the thicknesses of the first inorganic film INL1, the organic film OL, and/or the second inorganic film INL2 may be variously changed.

According to some embodiments, the particle PCT may be located under the first inorganic film INL1. The first inorganic film INL1 may cover a surface of the particle PTC. Alternatively, as shown in FIG. 9, the particle PTC may be located between the first inorganic film INL1 and the organic film OL. In this case, the organic film OL may cover a surface of the particle PTC.

A layer located on the particle PTC may include a curved portion CP due to the particle PTC. The curved portion CP may protrude in the third direction (Z-axis direction). For example, the first inorganic film INL1, the organic film OL, the second inorganic film INL2, the first insulating layer INS1, and/or the second insulating layer INS2 located on the particle PCT may include the curved portion CP.

According to some embodiments, a protective layer RPL may be located on the curved portion CP to prevent the curved portion CP from being exposed and etched in the process of manufacturing the display device. The protective layer RPL may be located on the curved portion CP of the first inorganic film INL1, the organic film OL, the second inorganic film INL2, the first insulating layer INS1, and/or the second insulating layer INS2. The protective layer RPL may cover the curved portion CP of the first inorganic film INL1, the organic film OL, the second inorganic film INL2, the first insulating layer INS1, and/or the second insulating layer INS2. The protective layer RPL may overlap the particle PTC in the third direction (Z-axis direction).

The protective layer RPL may include a metallic material. For example, the protective layer RPL may be made of tungsten (W), titanium (Ti), molybdenum (Mo), copper (Cu), aluminum (Al), or silver (Ag), but embodiments according to the present disclosure are not necessarily limited thereto. A thickness of the protective layer RPL in the third direction (Z-axis direction) may be thinner than that of the second inorganic film INL2. However, embodiments according to the present disclosure are not necessarily limited thereto, and the thicknesses of the protective layer RPL and the second inorganic film INL2 may be variously changed.

The third insulating layer INS3 may be located on the protective layer RPL. The protective layer RPL may be located between the second insulating layer INS2 and the third insulating layer INS3.

Hereinafter, a method of manufacturing the display device according to the above-described embodiments will be described.

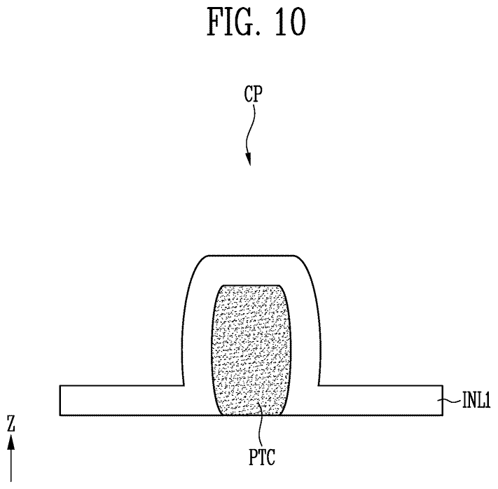

FIG. 10 to FIG. 16 illustrate cross-sectional views of process steps of a manufacturing method of a display device according to some embodiments. FIG. 10 to FIG. 16 are cross-sectional views for explaining a manufacturing method of the display device of FIG. 1 to FIG. 8, and are briefly shown for better understanding and ease of description, and detailed symbols therein are omitted.

Referring to FIG. 10, first, the first inorganic film INL1 of the thin film encapsulation layer TFE is formed. According to some embodiments, the particle PTC may exist below the first inorganic film INL1. The particles PCT may be foreign substances generated during a process of manufacturing the display device. The first inorganic film INL1 may be directly formed on the surface of the particle PTC. The first inorganic film INL1 may cover a surface of the particle PTC. The first inorganic film INL1 may include the curved portion CP due to the particle PTC. The curved portion CP may protrude in the third direction (Z-axis direction).

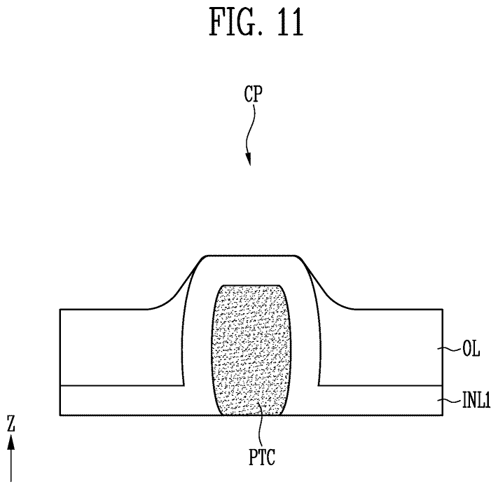

Referring to FIG. 11, next, the organic film OL is formed on the first inorganic film INL1. The organic film OL may be directly formed on the first inorganic film INL1. The organic film OL may include the curved portion CP due to the particle PTC.

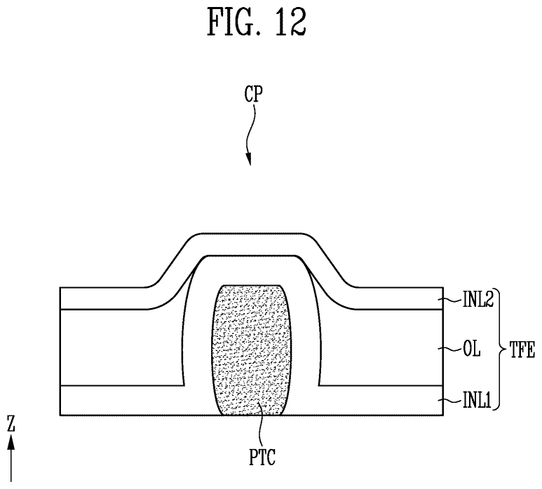

Referring to FIG. 12, the second inorganic film INL2 is formed on the organic film OL. The second inorganic film INL2 may be directly formed on the organic film OL. The second inorganic film INL2 may include the curved portion CP due to the particle PTC.

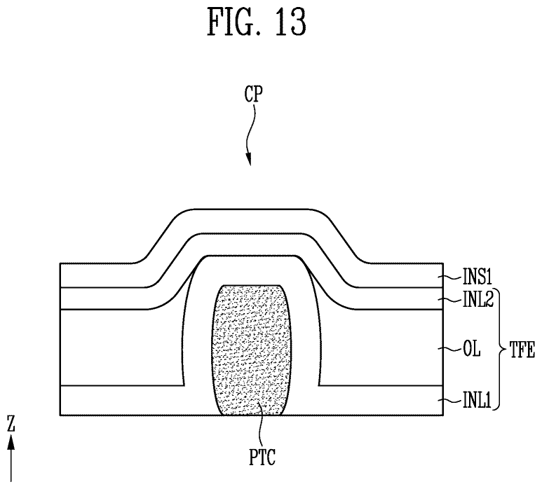

Referring to FIG. 13, then, the first insulating layer INS1 is formed on the second inorganic film INL2. The first insulating layer INS1 may be directly formed on the second inorganic film INL2. The second inorganic film INS2 may include the curved portion CP due to the particle PTC.

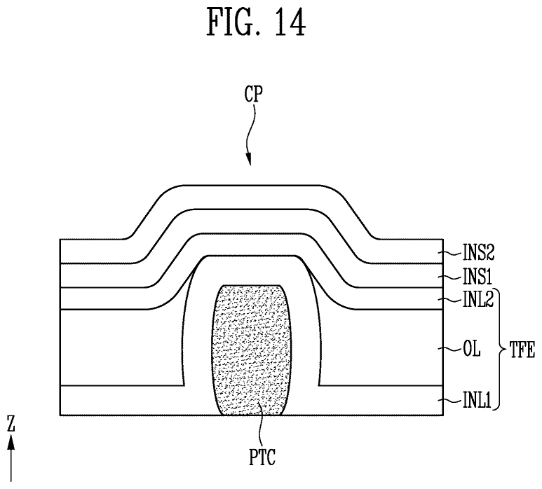

Referring to FIG. 14, then, the first conductive layer (MT1 in FIG. 4) is formed on the first insulating layer INS1, and the second insulating layer INS2 is formed on the first conductive layer MT1. The second insulating layer INS2 may be directly formed on the first conductive layer MT1 and/or first insulating layer INS1. The second insulating layer INS2 may include the curved portion CP due to the particle PTC.

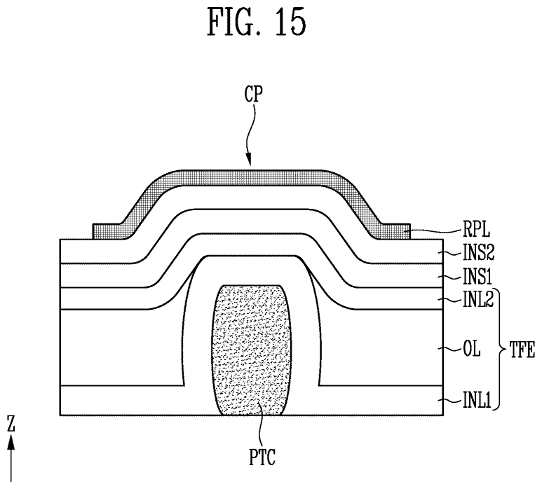

Referring to FIG. 15, the protective layer RPL is then formed on the second insulating layer INS2. The protective layer RPL may serve to prevent or reduce instances of a layer located below, for example, the thin film encapsulation layer TFE, from being etched in the process of etching the second insulating layer INS2 or the like to be described later. The protective layer RPL may be formed on the curved portion CP of the first inorganic film INL1, the organic film OL, the second inorganic film INL2, the first insulating layer INS1, and/or the second insulating layer INS2. The protective layer RPL may cover the curved portion CP of the first inorganic film INL1, the organic film OL, the second inorganic film INL2, the first insulating layer INS1, and/or the second insulating layer INS2. The protective layer RPL may overlap the particle PTC in the third direction (Z-axis direction).

The protective layer RPL may be made of a metallic material. For example, the protective layer RPL may be made of tungsten (W), titanium (Ti), molybdenum (Mo), copper (Cu), aluminum (Al), or silver (Ag), but embodiments according to the present disclosure are not limited thereto. The thickness of the protective layer RPL in the third direction (Z-axis direction) may be formed to be thinner than that of the second inorganic film INL2. However, embodiments according to the present disclosure are not necessarily limited thereto, and the thicknesses of the protective layer RPL and the second inorganic film INL2 may be variously changed.

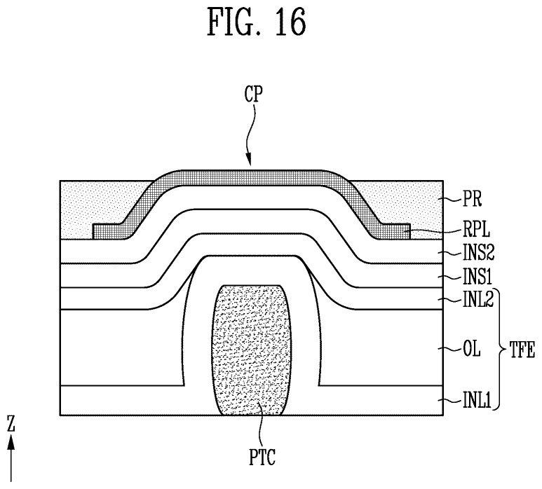

Referring to FIG. 16, the second insulating layer INS2 is then etched. For example, the contact holes (CNT1 and CNT2 in FIG. 7) may be formed by etching the second insulating layer INS2. In order to etch the second insulating layer INS2, a photoresist PR may be formed on the second insulating layer INS2 and/or the protective layer RPL. The photoresist PR may be relatively thinly formed on the curved portion CP, and may partially expose the curved portion CP. As described above, even if the photoresist PR is thinly formed on the curved portion CP or the curved portion CP is exposed by the photoresist PR, the protective layer RPL is formed on the curved portion CP, so that a layer located therebelow, for example, etching of the thin film encapsulation layer TFE or the like may be prevented or reduced. That is, because damage to the thin film encapsulation layer TFE in the process of forming the sensing layer TS may be prevented or reduced, the reliability of the display device may be relatively improved by minimizing or reducing external moisture permeation due to damage to the thin film encapsulation layer TFE.

Subsequently, the second conductive layer (MT2 in FIG. 4) is formed on the second insulating layer INS2, and the third insulating layer INS3 is formed on the protective layer RPL and/or the second conductive layer MT2, thereby completing the display device. The third insulating layer INS3 may be directly formed on the protective layer RPL, the second conductive layer MT2, and/or the second insulating layer INS2.

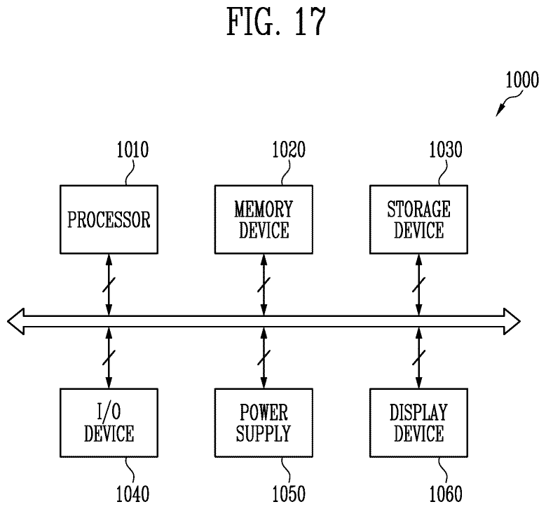

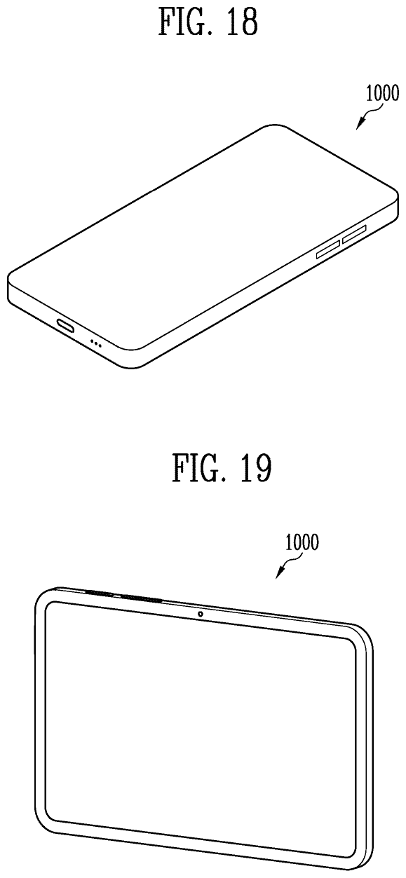

FIG. 17 is a schematic block diagram illustrating an electronic device 1000 including a display device in accordance with an embodiment. FIG. 18 is a schematic diagram illustrating an example where the electronic device 1000 of FIG. 17 is a smartphone. FIG. 19 is a schematic diagram illustrating an example where the electronic device 1000 of FIG. 17 is a tablet computer.

Referring to FIGS. 17 to 19, the electronic device 1000 may include a processor 1010, a memory device 1020, a storage device 1030, an input/output (I/O) device 1040, a power supply 1050, and a display device 1060. The display device 1060 may be the display device DD of FIG. 1. The electronic device 1000 may further include various ports for communication with a video card, a sound card, a memory card, a USB device, or other systems. In an embodiment, as illustrated in FIG. 18, the electronic device 1000 may be a smartphone. In an embodiment, as illustrated in FIG. 19, the electronic device 1000 may be a tablet computer. However, the aforementioned examples are illustrative, and the electronic device 1000 is not necessarily limited to the aforementioned examples. For example, the electronic device 1000 may be a cellular phone, a video phone, a smart pad, a smartwatch, a navigation device for vehicles, a computer monitor, a laptop computer, a head-mounted display device, or the like.

The processor 1010 may perform specific calculations or tasks. In an embodiment, the processor 1010 may include at least one of a central processing unit, an application processor, a graphic processing unit, a communication processor, an image signal processor, a controller, or the like. The processor 1010 may be connected to other components through an address bus, a control bus, a data bus, and the like. In an embodiment, the processor 1010 may be connected to an expansion bus such as a peripheral component interconnect (PCI) bus. In an embodiment, the processor 1010 may provide input image data to the display device 1060. Hence, the display device 1060 may display an image based on the input image data provided from the processor 1010.

The memory device 1020 may store data needed to perform the operation of the electronic device 1000. The memory device 1020 may function as a working memory and/or a buffer memory for the processor 1010. For example, the memory device 1020 may include one or more volatile memory devices such as a dynamic random access memory (DRAM) device, a static random access memory (SRAM) device, and a mobile DRAM device.

The storage device 1030 may store data in response to control signals or data from the processor 1010. The storage device 1030 may include one or more non-volatile storages to retain the data even when the electronic device 1000 is powered off. In some embodiments, the storage device 1030 may include a solid state drive (SSD), a hard disk drive (HDD), a CD-ROM, or the like.

The I/O device 1040 may include input devices such as a keyboard, a keypad, a touchpad, a touch screen, and a mouse, and output devices such as a speaker and a printer. In an embodiment, the display device 1060 may be integrated with the I/O device 1040.

The power supply 1050 may supply power needed to perform the operation of the electronic device 1000. For example, the power supply 1050 may include a power management integrated circuit (PMIC). In an embodiment, the power supply 1050 may supply power to the display device 1060.

The display device 1060 may display images in response to image data signals and/or control signals from the processor 1010. The display device 1060 may be connected to other components through the buses or other communication links.

Those skilled in the art related to the present embodiments will readily appreciate that many modifications are possible without materially departing from the novel teachings and advantages. The embodiments should be considered in a descriptive sense only and not for purposes of limitation. The scope of the present disclosure, not by the detailed description given in the appended claims, and their equivalents, and all differences within the equivalent scope will be construed as being included in embodiments according to the present disclosure.

What is claimed is:

1. A display device comprising:
a light emitting element;
a thin film encapsulation layer on the light emitting element;
a particle within the thin film encapsulation layer;
a first insulating layer on the thin film encapsulation layer;
a second insulating layer on the first insulating layer; and
a protective layer on the second insulating layer and overlapping the particle,
wherein the protective layer covers the thin film encapsulation layer, the first insulating layer, and the second insulating layer.

2. The display device of claim 1, wherein
the thin film encapsulation layer includes a first inorganic film, a second inorganic film, and an organic film between the first inorganic film and the second inorganic film.

3. The display device of claim 2, wherein the first inorganic film covers a surface of the particle.

4. The display device of claim 2, wherein a thickness of the second inorganic film is thicker than a thickness of the protective layer.

5. The display device of claim 4, wherein a thickness of the first inorganic film is thicker than a thickness of the second inorganic film.

6. The display device of claim 1, further comprising a first conductive layer between the first insulating layer and the second insulating layer.

7. The display device of claim 6, further comprising a second conductive layer on the second insulating layer.

8. The display device of claim 7, wherein the first conductive layer includes first sensing electrodes arranged in a first direction and second sensing electrodes arranged in a second direction intersecting the first direction, and the second conductive layer includes a connection electrode connecting the first sensing electrodes.

9. The display device of claim 7, further comprising a third insulating layer on the second conductive layer.

10. The display device of claim 9, wherein the protective layer is between the second insulating layer and the third insulating layer.

11. A display device comprising:
a light emitting element;
a thin film encapsulation layer on the light emitting element;
a particle within the thin film encapsulation layer;
an insulating layer on the thin film encapsulation layer,
wherein the encapsulation layer and the insulating layer include a curved portion that overlaps the particle; and
a protective layer on the insulating layer and covering the curved portion is included.

12. The display device of claim 11, wherein the thin film encapsulation layer includes a first inorganic film, a second inorganic film, and an organic film between the first inorganic film and the second inorganic film.

13. The display device of claim 12, wherein the first inorganic film covers a surface of the particle.

14. The display device of claim 12, wherein a thickness of the second inorganic film is thicker than a thickness of the protective layer.

15. The display device of claim 14, wherein a thickness of the first inorganic film is thicker than a thickness of the second inorganic film.

16. The display device of claim 11, wherein the protective layer includes a metallic material.

17. The display device of claim 11, wherein the insulating layer includes a first inorganic insulating layer on the thin film encapsulation layer and a second inorganic insulating layer on the first inorganic insulating layer.

18. The display device of claim 17, wherein the protective layer is on the second inorganic insulating layer.

19. The display device of claim 18, wherein the insulating layer further includes an organic insulating layer on the second inorganic insulating layer.

20. The display device of claim 19, wherein the protective layer is between the second inorganic insulating layer and the organic insulating layer.

21. An electronic device comprising:
a processor to provide input image data; and
a display device to display an image based on the input image data, the display device including sub-pixel areas,
wherein the display device comprises:
a light emitting element;
a thin film encapsulation layer on the light emitting element;
a particle within the thin film encapsulation layer;
a first insulating layer on the thin film encapsulation layer;
a second insulating layer on the first insulating layer; and
a protective layer on the second insulating layer and overlapping the particle,
wherein the protective layer covers the thin film encapsulation layer, the first insulating layer, and the second insulating layer.
